(19) United States
(12) Patent Application Publication
(10) Pub. No.: US 2024/0237559 A1
(43) Pub. Date: Jul. 11, 2024

(54) METHOD FOR FABRICATING SELECTOR AND SEMICONDUCTOR DEVICE INCLUDING THE SAME

(71) Applicant: SK hynix Inc., Icheon-si (KR)

(72) Inventors: Keo Rock CHOI, Icheon-si (KR); Cha Deok DONG, Icheon-si (KR)

(21) Appl. No.: 18/345,817

(22) Filed: Jun. 30, 2023

(30) Foreign Application Priority Data
Jan. 11, 2023 (KR) 10-2023-0004012

(51) Int. Cl. H10N 70/00; H10B 53/30; H10B 61/00; H10B 63/00

(52) U.S. Cl. CPC H10N 70/046; H10B 53/30; H10B 61/10; H10B 63/22; H10N 70/043; H10N 70/25

(57) ABSTRACT

A method for fabricating a selector may include: forming an insulating layer; doping the insulating layer with dopants by performing an ion implantation process; and performing a subsequent process to the insulating layer doped with the dopants for restoring damage caused by the ion implantation process.

### PRIORITY CLAIM AND CROSS-REFERENCE TO RELATED APPLICATION

This patent document claims the priority and benefits of Korean Patent Application No. 10-2023-0004012 filed on Jan. 11, 2023, which is incorporated herein by reference in its entirety.

### TECHNICAL FIELD

This patent document relates to integrated circuit designs and their applications in semiconductor devices or systems including memory circuits or devices.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include, but are not limited, memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

The disclosed technology in this patent document relates to designs and fabrication of selectors in integrated circuits or devices and their applications in semiconductor devices or systems including memory circuits or devices. Various implementations of a semiconductor device can improve the performance of a semiconductor device and reduce manufacturing defects.

In one aspect, a method for fabricating a selector for implementing the disclosed technology may include: forming an insulating layer; doping the insulating layer with dopants by performing an ion implantation process; and performing a process to the insulating layer doped with the dopants for restoring damage caused by the ion implantation process.

In another aspect, a method for fabricating a semiconductor device for implementing the disclosed technology may include: forming an insulating layer; doping the insulating layer with dopants by performing an ion implantation process; and performing a subsequent process for restoring damage caused by the ion implantation process wherein the insulating layer is formed as a selector layer after the ion implantation process and the subsequent process; forming a memory layer over or under the selector layer; and etching the memory layer and the selector layer by using a mask pattern to form a memory cell including a memory pattern and a selector pattern.

The above and other aspects of the disclosed technology are disclosed in the drawings, the detailed description and the claims.

### BRIEF DESCRIPTION OF THE DRAWINGS

FIGS. 1A to 1C illustrate an example of a method for forming a selector based on some implementations of the disclosed technology.

FIG. 2 illustrates a change of an ion implanted insulating layer depending on the RF power of a plasma treatment process performed as a post-process on the ion implanted insulating layer.

FIG. 3 illustrates a change of an ion implanted insulating layer depending on the RF power of a plasma treatment process performed as a post-process on the ion implanted insulating layer.

FIGS. 4A and 4B illustrate an example of a semiconductor device based on some implementations of the disclosed technology.

FIGS. 5A to 5G illustrate an example of a method for a semiconductor device based on some implementations of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

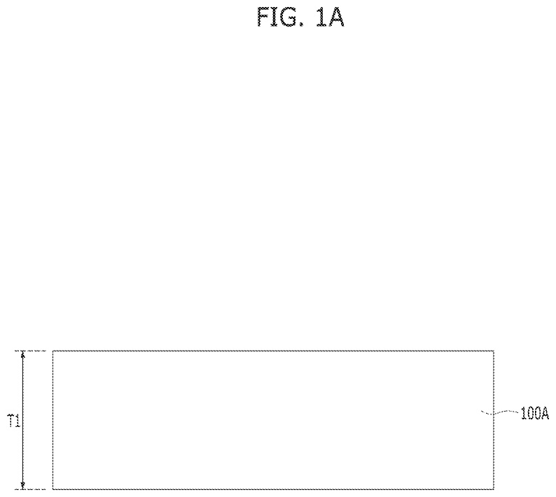

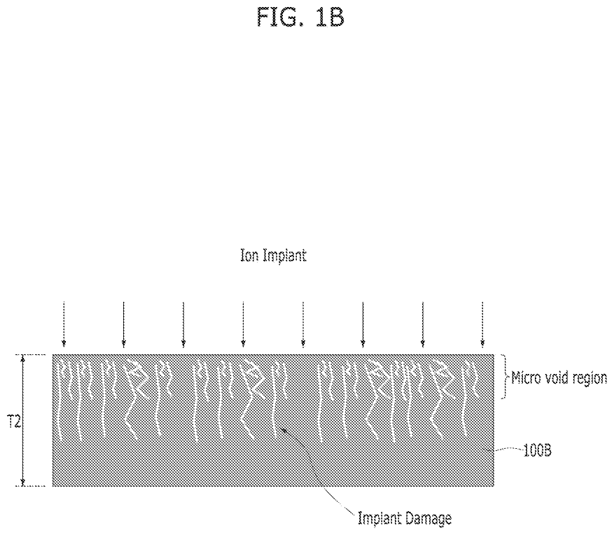

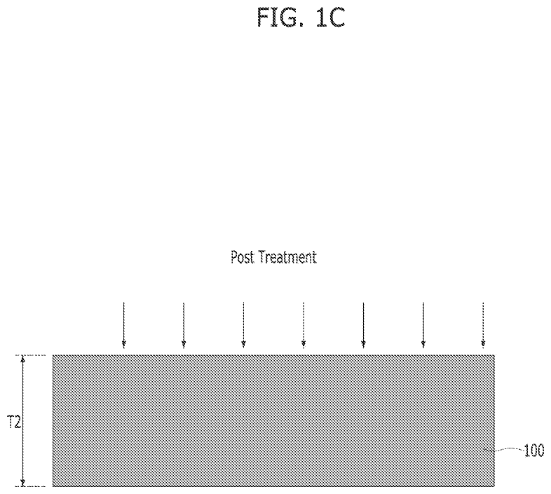

FIGS. 1A to 1C illustrate an example of a method for forming a selector 100 based on some implementations of the disclosed technology.

The selector 100 is a layer that is structured to function as a current control layer capable of controlling the current flow through the layer in response to an applied voltage and can be used in various semiconductor devices. For example, in a semiconductor memory device within memory cells each formed by a stack of layers that include the selector 100, the selector 100 can be used to prevent a current leakage in such memory cells. In some implementations, the selector 100 may have a threshold switching characteristic that blocks or substantially limits a current when a magnitude of an applied voltage to the selector 100 is less than a predetermined threshold value and allows the passage of the current to increase rapidly when the magnitude of the applied voltage is equal to or greater than the predetermined threshold value. This threshold value may be referred to as a threshold voltage, and the selector 100 may controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector 100 exhibits different electrically conductive states to provide a switching operation to switch between the different electrically conductive states by controlling the applied voltage relative to the threshold voltage.

In various implementations, the selector 100 may include an insulating material and a dopant.

In some implementations, the insulating material included in the selector 100 may include an oxide, a nitride, or an oxynitride, or a combination thereof. For example, the insulating material may include silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride, or a combination thereof.

The dopant included in the selector 100 may include an n-type dopant or a p-type dopant. The dopant may include one or more of boron (B), nitrogen (N), carbon (C), phosphorous (P), arsenic (As), aluminum (Al), silicon (Si), gallium (Ga), tungsten (W), antimony (Sb) or a germanium (Ge). For example, the selector 100 may include As-doped silicon oxide or Ge-doped silicon oxide in some applications.

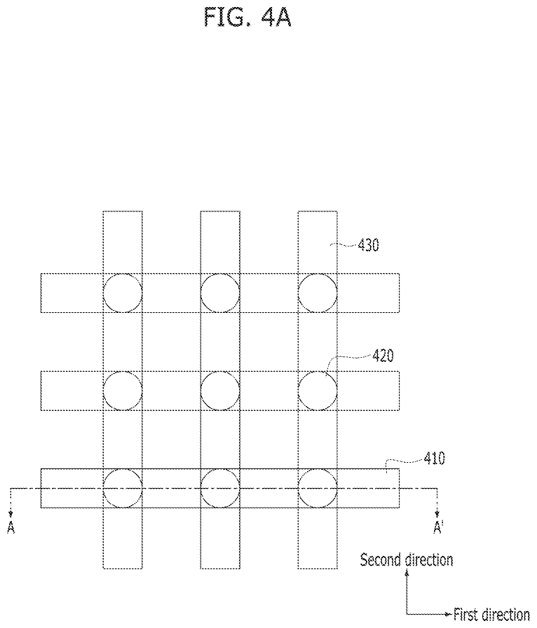

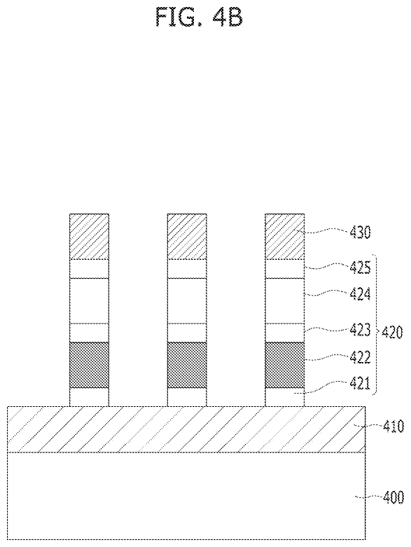

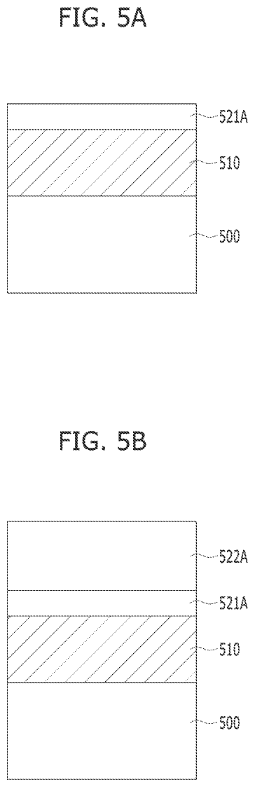

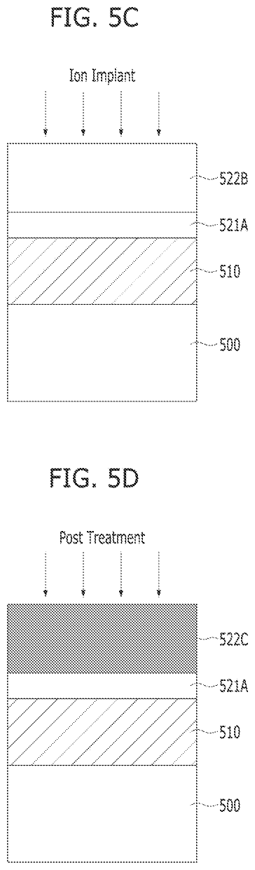

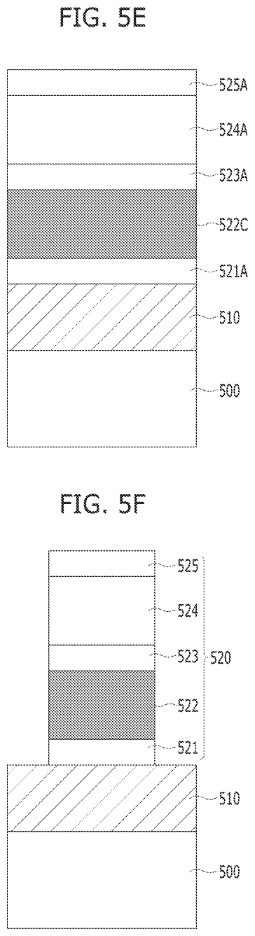

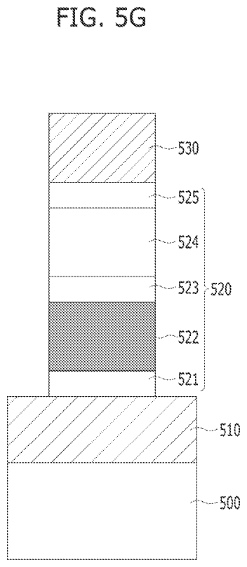

In the implementation shown in FIGS. 1A to 1C, a method for forming the selector 100 is described and the description of structures associated with the selector 100 is omitted in FIGS. 1A to 1C. Description on certain aspects of the structures other than the selector 100 is provided in a later part of this patent document with reference to FIGS. 4A to 5G.

The selector 100 may include an insulating material and a dopant doped in the insulating material. Referring to FIG. 1A, an insulating layer 100A for the selector is first formed.

In some implementations, the insulating layer 100A may include an oxide, a nitride, or an oxynitride, or a combination thereof. In various implementations of the selector 100 for memory devices, the insulating layer 100 for the selector 100 may include an oxide or a nitride. For example, the insulating layer 100A may include silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride or a combination thereof.

The insulating layer 100A may be formed to have a thickness T1 as shown in FIG. 1A.

Referring to FIG. 1B, an ion implantation process may be performed on the insulating layer 100A to implant an dopant into the insulating layer 100A. The insulating layer 100A doped with a dopant by the ion implantation process may be referred to as an ion implanted insulating layer 100B.

The ion implanted insulating layer 100B may be formed to have a thickness T2. Since an upper portion of the insulating layer 100A may be partially removed, the thickness T2 of the ion implanted insulating layer 100B may be smaller than the thickness T1 of the insulating layer 100A.

The dopant doped by the ion implantation process may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si), gallium (Ga), tungsten (W), antimony (Sb), or germanium (Ge).

The ion implantation process may be performed at different energy levels. In some cases, damage in the ion implanted insulating layer 100B may be caused by the ion implantation process. Such damage may be continuously accumulated at an upper portion of the implanted insulating layer 100B.

The ion implantation process may cause certain damage to the ion implanted insulating layer 100B. For example, a micro void region may be undesirably formed at the upper portion of the ion implanted insulating layer 100B. For example, when an As—SiO₂ layer is formed by doping a silicon oxide (SiO₂) layer with arsenic (As) as a dopant through the ion implantation process, arsenic (As) is agglomerated and exists as aggregates. If such arsenic (As) is diffused out during the process, only micro voids may remain in a site where arsenic (As) exited in the As—SiO₂ layer. Since such damage may accumulate at an upper portion of the As—SiO₂ layer, the micro voids may be formed at the upper portion of the As—SiO₂ layer. Such micro voids may act as a major factor contributing to deteriorating the durability of the selector. Further, such damage may affect not only the physical durability of the selector but also the state of the dopant, which causes the deterioration of the switching operation characteristics of the selector. When the physical durability of the selector is deteriorated by such damage, a lifting phenomenon may occur as layers having various stresses are continuously stacked.

In the implementations, a post treatment process for restoring damage present in the ion implanted insulating layer can be performed to prevent deterioration of durability and switching operation characteristics of the selector.

Referring to FIG. 1C, after the ion implantation process, a post treatment process may be performed to restore damage generated in the ion implanted insulating layer 100B. In the description below, the damage occurring in the ion implanted insulating layer 100B and caused by the ion implantation process may be referred to as the ion implantation damage. The ion implanted insulating layer 100B in which the ion implantation damage is restored by the post treatment process may correspond to a selector 100.

A thickness T3 of the selector 100 may be the substantially same as the thickness T2 of the ion implanted insulating layer 100B.

The post treatment process may be performed to suppress or minimize the micro voids by minimizing aggregation of the dopant incorporated by the ion implantation process and uniformly dispersing the dopant in the ion implanted insulating layer 100B. The post treatment process may be performed under appropriate conditions to restore the physical damage of the ion implanted insulating layer 100B by re-distributing the dopant. As discussed above, the dopants are introduced into the insulating layer 100 by the ion implantation process. The introduced dopants are distributed in the insulating layer 100 to form the ion implanted insulating layer 100B and those dopants are redistributed by the post treatment process. By redistributing dopants, it is possible to prevent the dopant from diffusing out of the ion implanted insulating layer 100B or moving downward to be distributed at an interface with a layer disposed below the ion implanted insulating layer 100B, and maintain a metallic state of the dopant.

In some implementations, the post treatment process may be performed by a plasma treatment process or a thermal treatment process.

In the below, the plasma treatment process will be described.

A gas used in the plasma treatment process may include an inert gas, or oxygen, or a combination thereof.

Examples of the inert gas may include nitrogen, hydrogen, helium, argon, or others.

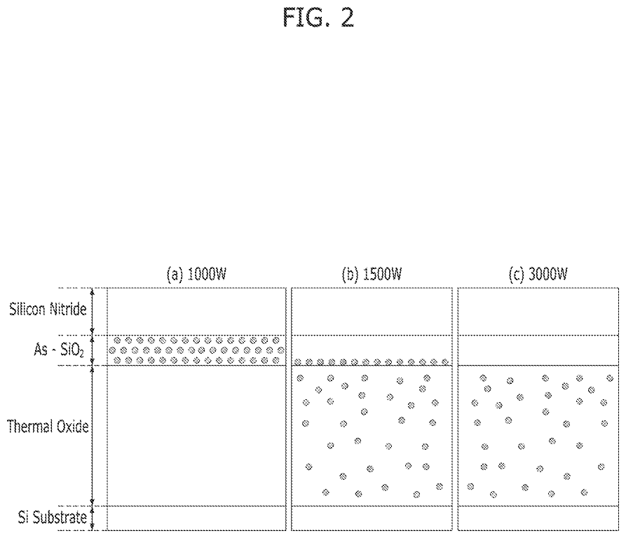

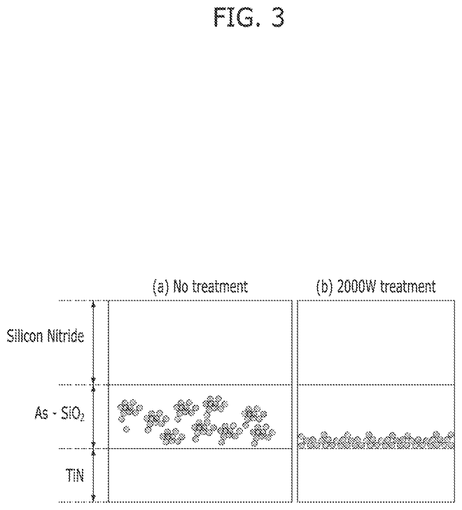

When the gas used in the plasma treatment process does not contain oxygen, the RF Power applied during the plasma treatment process may be in the range of 100 W to 1000 W. When the RF Power is less than 100 W, it is difficult to sufficiently restore the damage in the ion implanted insulating layer 100B. When the RF Power is greater than 1000 W, the dopant is diffused to be outside of the ion implanted insulating layer 100B or moves downward to be located at an interface between the ion implanted insulating layer 100B and the layer disposed below the ion implanted insulating layer 100B, which makes it difficult to form an electrical path. As a result, the selector 100 cannot operate normally. This will be described with reference to FIGS. 2 and 3.

FIG. 2 illustrates different distributions of arsenic (As) in an ion implanted insulating layer depending on the RF power of a plasma treatment process performed as a post-process on the ion implanted insulating layer. In FIG. 2, the arsenic (As) is shown as the example only but the similar description can be applied to the dopant other than arsenic (As). FIG. 2 is a schematic diagram of a structure in which a thermal oxide layer, an arsenic (As) doped silicon oxide layer (As—SiO₂ layer) and a silicon nitride layer are sequentially stacked over a silicon substrate. In FIG. 2, the arsenic (As) doped silicon oxide layer (As—SiO₂ layer) is an example of the ion implanted insulating layer. In FIG. 2, cases (a), (b) and (c) show different distributions of arsenic (As) when the plasma treatment process are performed as a post treatment process at different RF power levels. The hatched circle shown in FIG. 2 represents arsenic (As).

A change of the arsenic (As) profile depending on the RF power applied during the plasma treatment process is to be discussed with the example of the structure as shown in FIG. 2. The structure shown in FIG. 2 may be formed by forming the thermal oxide layer over the Si substrate, forming the silicon oxide layer over the thermal oxide layer, doping the silicon oxide layer with arsenic (As) by the ion implantation process, performing the plasma treatment process on the arsenic (As) doped silicon oxide layer (As—SiO₂ layer) and forming the silicon nitride layer over the As—SiO₂ layer. The plasma treatment was performed on the structure as shown in FIG. 2 using an inert gas containing no oxygen and at the RF power level of 1000 W, 1500 W, and 3000 W. The cases (a) to (c) as shown in FIG. 2 correspond to the RF power level of 100 W, 1500 W, and 3000 W, respectively.

For the case (a), when the plasma treatment was performed with the RF power of 1000 W, it was shown that arsenic (As) was evenly dispersed inside the As—SiO₂ layer and no micro voids were present. Thus, when the RF power of 1000 W was applied during the plasma treatment, the physical damage of the As-doped silicon oxide layer (As—SiO₂ layer) caused by the ion implantation could be restored and the As—SiO₂ has a good As profile without any negative effects.

For the case (b), when the plasma treatment process was performed at the RF power of 1500 W, As was diffused out from the As-doped silicon oxide layer (As—SiO₂ layer) and moved to the thermal oxide layer disposed below the As—SiO₂ layer. In addition, a part of arsenic (As) remained at an interface between the As—SiO₂ layer and the thermal oxide layer. For the case (c), when the plasma treatment process was performed at the RF power of 3000 W, As was completely diffused out from the As—SiO₂ layer and moved to the thermal oxide layer disposed below the As—SiO₂ layer. In addition, there was no arsenic (As) remained at an interface between the As—SiO₂ layer and the thermal oxide layer.

As such, when the plasma treatment process is performed at the RF power exceeding 1000 W, arsenic (As) in the As—SiO₂ layer is diffused out. Thus, arsenic (As) is lost from the As—SiO₂ layer, which causes the selector to cannot operate normally.

Another example showing a change of the arsenic (As) distribution in the As—SiO₂ layer depending on RF power levels applied during the plasma treatment is to be discussed with reference to FIG. 3.

FIG. 3 illustrates different distributions of arsenic (As) in an ion implanted insulating layer depending on the RF power of a plasma treatment process performed as a post-process for the ion implanted insulating layer. In FIG. 3, the arsenic (As) is shown as the example only but the similar description can be applied to the dopant other than arsenic (As). FIG. 3 is a schematic diagram of a structure in which a TiN layer and an arsenic (As) doped silicon oxide layer (As—SiO₂ layer) are sequentially stacked. In FIG. 3, the arsenic (As) doped silicon oxide layer (As—SiO₂ layer) is an example of the ion implanted insulating layer. In FIG. 3, case (a) shows when any post treatment process is not performed after an ion implantation process and case (b) shows when a plasma treatment process is performed at the RF power level of 2000 W after the ion implantation process. The hatched circle shown in FIG. 3 represents arsenic (As).

A change of the distribution of arsenic (As) when the plasma treatment is performed at the RF power level greater than 1000 W is to be discussed with the example of the structure as shown in FIG. 3. The structure shown in FIG. 3 was formed by forming a silicon oxide layer over the TiN layer, doping the silicon oxide layer with arsenic (As) by the ion implantation process to form the arsenic (As) doped silicon oxide layer (As—SiO₂ layer) and forming a silicon nitride layer over the As—SiO₂ layer (a), or by forming a silicon oxide layer over the TiN layer, doping the silicon oxide layer with arsenic (As) by the ion implantation process, performing the plasma treatment process with the RF power of 2000 W and forming a silicon nitride layer over the As—SiO₂ layer. The plasma treatment process was performed using a gas containing no oxygen.

For the case (a), when the plasma treatment process was not performed, it was shown that arsenic (As) was distributed in the As—SiO₂ layer as an agglomerated aggregate.

For the case (b), when the plasma treatment was performed at the RF power level of 2000 W, it was shown that arsenic (As) was moved to be distributed at an interface between the As—SiO₂ layer and the TiN layer. In the cases (b) and (c) of FIG. 2, arsenic (As) was diffused out from the As—SiO₂ layer when the plasma treatment was performed at the high RF power levels such as 1500 W and 3000 W. In FIG. 2, since the thermal oxide layer did not block arsenic (As), the diffused arsenic (As) could be moved to the thermal oxide layer. Unlike FIG. 2, in case of FIG. 3, since the TiN layer was disposed below the As—SiO₂ layer, arsenic (As) cannot be diffused into the TiN layer and the moved arsenic (As) is located at the interface between the As—SiO₂ layer and the TiN layer.

Thus, in the case (b) of FIG. 3, after performing the plasma treatment at the high RF power level of 2000 W, arsenic (As) is not evenly distributed throughout the As—SiO₂ layer and located at the interface between the As—SiO₂ layer and the TiN layer, which makes it difficult to form an electrical path. As a result, the selector cannot operate normally or as desired.

Referring to FIGS. 2 and 3, when the plasma treatment process is used as the post treatment process, the gas and the RF power used in the plasma treatment process can affect the dopant profile in the ion implanted insulating layer. The plasma treatment process is performed as the post treatment process to restore inevitable physical damage caused by the ion implantation process. To have desired benefits from the plasma treatment process, the gas and the RF power, which are used in the plasma treatment process, needs to be properly selected. When the plasma treatment process is performed using a gas containing no oxygen, the RF power may be preferably 1000 W or less. For example, a lower limit of the RF Power may be 100 W.

When the plasma treatment process is performed using oxygen, the durability of the selector can be improved by inducing the dispersion of arsenic (As) through bonds between arsenic (As) and O. However, when the degree of oxidation of arsenic (As) becomes too higher, it is difficult to maintain a metallic state in which arsenic (As) is independently present without bonding with other elements. If arsenic (As) does not completely maintain in a metallic state, the selector cannot properly exhibit its switching characteristics. Therefore, when oxygen is used in the plasma treatment process, the RF power needs to be carefully controlled.

In some implementations, when gas used in the plasma treatment process includes oxygen, the RF power may be in the range of 100 W to 500 W. When the RF Power is less than 100 W, it is difficult to sufficiently restore the damage in the ion implanted insulating layer 100B. When the RF power is greater than 500 W, the degree of oxidation of arsenic (As) becomes severe, which results in excessive loss of arsenic (As) in a metallic state. As a result, the switching characteristic of the selector may be deteriorated.

The plasma treatment process may be performed as the post treatment process for restoring the damage to the ion implanted insulating layer 100B caused by the ion implantation process. The plasma treatment process may be performed by appropriately controlling a reaction gas and Rf power conditions such that the dopant in the ion implanted insulating layer 100B can be evenly distributed. Accordingly, the physical damage can be restored without affecting the dopant profile, and a metallic state of the dopant can be maintained.

In some implementations, the thermal treatment process can be performed as the post treatment. In the below, the thermal treatment process will be described.

The post treatment process for restoring the physical damage caused by the ion implantation process may be performed by the thermal treatment process.

A temperature of the thermal treatment process needs to be appropriately controlled such that the dopant is redistributed in the ion implanted insulating layer 100B to restore the physical damage and that negative reactions such as migration or recrystallization of elements from other previously formed layers do not proceed.

In some implementations, the thermal treatment process may be performed at a temperature in the range of 100-400° C. When the temperature of the thermal treatment process is less than 100° C., it is difficult to sufficiently restore the physical damage caused by the ion implantation process. When the temperature of the thermal treatment process is greater than 400° C., migration or recrystallization of element from other previously formed metal layers may occur.

In some implementations, the thermal treatment process may be performed using the same gas as the gas used in the above-described plasma treatment process. For example, the thermal treatment process may be performed using oxygen, or an inert gas, or a combination thereof.

According to the implementation, the selector 100 may be normally operated by performing the post treatment process for restoring the damage caused by the ion implantation process. In addition, the physical durability of the selector 100 can be improved to secure a stress margin of layers deposited in subsequent processes. Further, it is possible to improve on/off operation characteristics of the selector 100 by preserving the metallic state of the dopant.

Through the above-described process, the selector 100 may be formed.

The selector 100 in accordance with the above-described implementation may form a semiconductor device together with a memory element. This will be described with reference to FIGS. 4A and 4B.

FIGS. 4A and 4B illustrate a semiconductor device based on some implementations of the disclosed technology. FIG. 4A is a plan view, and FIG. 4B is a cross-sectional view taken along line A-A′ of FIG. 4A. The descriptions similar to those with reference to FIGS. 1A to 1C, FIGS. 2 and 3 will be omitted.

Referring to FIGS. 4A and 4B, the semiconductor device may include a cross-point structure including a substrate 500, first conductive lines 510 formed over the substrate 500 and extending in a first direction, second conductive lines 530 formed over the first conductive lines 510 to be spaced apart from the first conductive lines 510 and extending in a second direction crossing the first direction, and memory cells 520 disposed at intersections of the first conductive lines 510 and the second conductive lines 530 between the first conductive lines 510 and the second conductive lines 530. In this patent document, the conductive lines can refer to any conductive structures that electrically connect two or more circuit elements in the semiconductor memory. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor memory.

The substrate 500 may include a semiconductor material such as silicon. A required lower structure (not shown) may be formed in the substrate 500. For example, the substrate 500 may include a driving circuit (not shown) electrically connected to the first conductive lines 510 and/or the second conductive lines 530 to control operations of the memory cells 520. In this patent document, the conductive lines can indicate conductive structures that electrically connect two or more circuit elements in the semiconductor device. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor device.

The first conductive lines 510 and the second conductive lines 530 may be connected to a lower end and an upper end of the memory cell 520, respectively, and may provide a voltage or a current to the memory cell 520 to drive the memory cell 520. When the first conductive lines 510 function as a word line, the second conductive lines 530 may function as a bit line. Conversely, when the first conductive lines 510 function as a bit line, the second conductive lines 530 may function as a word line. The first conductive lines 510 and the second conductive lines 530 may include a single-layered structure or a multi-layered structure including one or more of various conductive materials. Examples of the conductive materials may include a metal, a metal nitride, or a conductive carbon material, or a combination thereof, but are not limited thereto. For example, the first conductive lines 510 and the second conductive lines 530 may include at least one of tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 520 may be arranged in a matrix having rows and columns along the first direction and the second direction so as to overlap the intersection regions between the first conductive lines 510 and the second conductive lines 530. In an implementation, each of the memory cells 520 may have a size that is substantially equal to or smaller than that of the intersection region between each corresponding pair of the first conductive lines 510 and the second conductive lines 530. In another implementation, each of the memory cells 520 may have a size that is larger than that of the intersection region between each corresponding pair of the first conductive lines 510 and the second conductive lines 530.

In some implementations, the memory cell 520 may have a cylindrical shape, but the shape of the memory cell 520 is not limited thereto. In some implementations, the memory cell 520 may have a square pillar shape.

Spaces between the first conductive lines 510, the second conductive lines 530 and the memory cell 520 may be filled with an insulating material.

The memory cell 520 may include a stacked structure including a lower electrode 521, a selector pattern 522, a middle electrode 523, a memory pattern 524 and an upper electrode 525.

The selector pattern 522 shown in FIG. 4B may correspond to the selector 100 shown in FIG. 1C.

The lower electrode 521 may be interposed between the first conductive line 510 and the selector pattern 522 and disposed at a lowermost portion of each of the memory cells 520. The lower electrode 521 may function as a circuit node that carries a current or applies a voltage between one of the first conductive lines 510 and the remaining portion (e.g., the elements 522, 523, 524, and 525) of each of the memory cells 520. The middle electrode 523 may be interposed between the selector pattern 522 and the memory pattern 524. The middle electrode 523 may electrically connect the selector pattern 522 and the memory pattern 524 to each other while physically isolating or separating the selector pattern 522 and the memory pattern 524 from each other. The upper electrode 525 may be disposed at an uppermost portion of the memory cell 520 and function as a transmission path of electrical signals such as a voltage or a current between a material layer in the memory cell 520 and one of the second conductive lines 530.

The lower electrode 521, the middle electrode 523 and the upper electrode 525 may include a single-layered structure or a multi-layered structure including various conductive materials such as a metal, a metal nitride, a conductive carbon material, or a combination thereof, respectively. For example, the middle electrode 523 and the upper electrode 525 may include at least one of tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode 521, the middle electrode 523 and the upper electrode 525 may include the same material as each other or different materials from each other.

The lower electrode 521, the middle electrode 523 and the upper electrode 525 may have the same thickness as each other or different thicknesses from each other.

At least one of the lower electrode 521, the middle electrode 523 and the upper electrode layer may be omitted. For example, when the lower electrode 521 is omitted, the first conductive lines 510 may perform the function of the lower electrode 521, and when the upper electrode 525 is omitted, the second conductive lines 530 may perform the function of the upper electrode 525.

The selector pattern 522 may function as a current control layer capable of controlling the current flow and prevent a current leakage between the memory cells 520 sharing the first line 510 or the second line 530. In some implementations, the selector pattern 522 may have a threshold switching characteristic that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector pattern 522 may controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector pattern 522 exhibits different electrically conductive states to provide a switching operation to switch between the different electrically conductive states by controlling the applied voltage relative to the threshold voltage.

In some implementations, the selector pattern 522 may perform a threshold switching operation through a doped region formed in a material layer for the selector pattern 522. Thus, a size of the threshold switching operation region may be controlled by a distribution area of the dopants. The dopants may form trap sites for charge carriers in the material layer for the selector pattern 522. The trap sites may capture the charge carriers moving in the selector pattern 522 based on an external voltage applied to the selector pattern 522. The trap sites thereby provide a threshold switching characteristic and are used to perform a threshold switching operation.

In some implementations, the selector pattern 522 may include an insulating material and a dopant.

In some implementations, the insulating material included in the selector pattern 522 may include at least one of an oxide, a nitride, or an oxynitride, or a combination thereof. For example, the insulating material may include silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride, or a combination thereof. The dopant included in the selector pattern 522 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) or germanium (Ge). For example, the selector pattern 522 may include As-doped silicon oxide or Ge-doped silicon oxide.

The memory pattern 524 may be used to store data by switching between different resistance states according to an applied voltage or current. The memory pattern 524 may have a single-layered structure or a multi-layered structure including at least one of materials having a variable resistance characteristic used for an RRAM, a PRAM, an MRAM, an FRAM, and others. For example, the memory pattern 524 may include a metal oxide such as a transition metal oxide or a perovskite-based oxide, a phase change material such as a chalcogenide-based material, a ferromagnetic material, a ferroelectric material, or others. However, the implementations are not limited thereto, and the memory cell 520 may include other variable resistance layers capable of storing data in various ways instead of the memory pattern 524. In some implementations, the memory pattern 524 may include an MTJ structure including a free layer having a variable magnetization direction, a pinned layer having a pinned magnetization direction and a tunnel barrier layer interposed between the free layer and the pinned layer.

The memory pattern 524 (may have a single-layered structure or a multi-layered structure including at least one of materials having a variable resistance characteristic. However, the implementations are not limited thereto, and the memory cell 520 may include other variable resistance layers capable of storing data in various ways instead of the memory pattern 524.

In some implementations, each of the memory cells 520 includes the lower electrode 521, the selector pattern 522, the middle electrode 523, the memory pattern 524 and the upper electrode 525 which are sequentially stacked. The structures of the memory cells 520 may be varied without being limited to one as shown in FIGS. 1A and 1B as long as the memory cells 520 have data storage properties. In some implementations, at least one of the middle electrode 523 and the upper electrode layer 525 may be omitted. In some implementations, relative positions of the memory pattern 524 and the selector pattern 522 may be reversed. In some implementations, in addition to the layers 521, 522, 523, 524 and 125 shown in FIG. 4B, the memory cells 520 may further include one or more layers (not shown) for enhancing characteristics of the memory cells 520 or improving fabricating processes. For example, the memory cell 520 may include at least one of a lower electrode contact and an upper electrode contact. Further, a hard mask pattern may remain.

In some implementations, neighboring memory cells of the plurality of memory cells 520 may be spaced apart from each other at a predetermined interval, and trenches may be present between the plurality of memory cells 520. A trench between neighboring memory cells 520 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 500. In some implementations, neighboring trenches may be spaced apart from each other by an equal or similar distance.

Although one cross-point structure has been described, two or more cross-point structures may be stacked in a vertical direction perpendicular to a top surface of the substrate 500.

A method for fabricating a semiconductor device will be explained with reference to FIGS. 5A to 5G. The detailed descriptions similar to those described in FIGS. 4A and 4B will be omitted. In the below description, a lower electrode layer 521A, a selector layer 522C, a middle electrode layer 523A, a memory layer 524A and an upper electrode layer 525A may represent material layers to form a lower electrode 521, a selector pattern 522, a middle electrode 523, a memory pattern 524 and an upper electrode 525, respectively, by a patterning process.

Referring to FIG. 5A, first conductive lines 510 may be formed over a substrate 500 in which a predetermined structure is formed. For example, the first conductive lines 510 may be formed by forming a conductive layer for the first conductive lines 510 over the substrate 200 and etching the conductive layer using a mask pattern in a line shape extending in a first direction. The first conductive lines 510 may have a single-layered structure or a multi-layered structure including a conductive material. Examples of the conductive material may include a metal, a metal nitride, or a conductive carbon, or a combination thereof.

The lower electrode layer 521A may be formed over the first conductive lines 510. The lower electrode layer 521A may have a single-layered structure or a multi-layered structure including various conductive materials such as a metal, a metal nitride, or a conductive carbon, or a combination thereof.

Referring to FIG. 5B, an insulating layer 522A for forming the selector layer 522C may be formed over the lower electrode layer 521A. The insulating layer 522A may include an oxide, a nitride, or an oxynitride, or a combination thereof. For example, the insulating layer 522A may include silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride, or a combination thereof.

Referring to FIG. 5C, an ion implantation process may be performed on the insulating layer 522A. The insulating layer doped with a dopant by the ion implantation process may be referred to as an ion implanted insulating layer 522B.

The dopant may include an n-type dopant or a p-type dopant. The dopant may include one or more of boron (B), nitrogen (N), carbon (C), phosphorous (P), arsenic (As), aluminum (Al), silicon (Si), gallium (Ga), tungsten (W), antimony (Sb) or a germanium (Ge).

The ion implantation process may be performed with different energies. At this time, damage due to ion implantation may occur in the ion implanted insulating layer 522B. In particular, such damage may be continuously accumulated at an upper portion of the implanted insulating layer 522B.

During the ion implantation process, damage inevitably occur in the ion implanted insulating layer 522B.

Referring to FIG. 5D, a post treatment process may be performed to restore the damage in the ion implanted insulating layer 522B.

The post treatment process may be performed under appropriate conditions to restore the physical damage of the ion implanted insulating layer 522B through re-distribution of the dopant, prevent the dopant from diffusing out of the ion implanted insulating layer 522B or moving downward to be distributed at an interface with a layer disposed below the ion implanted insulating layer 522B, and maintain a metallic state of the dopant.

The post treatment process may be performed by a plasma treatment process or a thermal treatment process.

A gas used in the plasma treatment process may include an inert gas, or oxygen, or a combination thereof. Examples of the inert gas may include nitrogen, hydrogen, helium, argon, and the like.

When the gas used in the plasma treatment process does not contain oxygen, the RF Power applied during the plasma treatment process may be in the range of 100 W to 1000 W. When the RF Power is less than 100 W, it is difficult to sufficiently restore the damage in the ion implanted insulating layer 522B. When the RF Power is greater than 1000 W, the dopant is diffused outside the ion implanted insulating layer 522B or moves downward and is distributed at an interface with the layer disposed below the ion implanted insulating layer 522B, making it difficult to form an electrical path. As a result, the selector pattern 522 cannot operate normally.

On the other hand, when the gas used in the plasma treatment process contains oxygen, the RF power may be in the range of 100 W to 500 W. When the RF Power is less than 100 W, it is difficult to sufficiently restore the damage in the ion implanted insulating layer 522B. When the RF power is greater than 500 W, the degree of oxidation of As becomes severe, resulting in excessive loss of As in a metallic state. As a result, the switching characteristic of the selector pattern 522 may be deteriorated.

A temperature of the thermal treatment process should be appropriately controlled such that the dopant is redistributed in the ion implanted insulating layer 522B to restore the physical damage and, at the same time, negative reactions such as migration or recrystallization of elements from other previously formed layers do not proceed. In some implementations, the thermal treatment process may be performed at a temperature in the range of 100-400° C.

In some implementations, the thermal treatment process may be performed using the same gas as the gas used in the above-described plasma treatment process. For example, the thermal treatment process may be performed using oxygen, or an inert gas, or a combination thereof.

Through the post treatment process, the selector layer 522C may be formed. Since the damage caused by the ion implantation process can be restored by the post treatment process and thus, the physical durability of the selector layer 522C can be improved, a stress margin of layers deposited in subsequent processes can be secured. Further, a metallic state of the dopant can be preserved. As a result, it is possible to improve on/off operation characteristics of the selector pattern 522.

Referring to FIG. 5E, the middle electrode layer 523A, the memory layer 524A and the upper electrode layer 525A may be sequentially formed over the selector layer 522C.

The middle electrode layer 523A may include a single-layered structure or a multi-layered structure including one or more of various conductive materials, such as a metal, a metal nitride, or a conductive carbon, or a combination thereof.

The memory layer 524A may have a single-layered structure or a multi-layered structure including at least one of materials having a variable resistance characteristic used for an RRAM, a PRAM, an MRAM, an FRAM, and others. For example, the memory layer 524A may include a metal oxide such as a transition metal oxide or a perovskite-based oxide, a phase change material such as a chalcogenide-based material, a ferromagnetic material, a ferroelectric material, or others.

The upper electrode layer 525A may include a single-layered structure or a multi-layered structure including one or more of various conductive materials, such as a metal, a metal nitride, or a conductive carbon, or a combination thereof.

Referring to FIG. 5F, a memory cell 520 in which the lower electrode 521, the selector pattern 522, the middle electrode 523, the memory pattern 524 and the upper electrode 525 are sequentially stacked may be formed by etching the upper electrode layer 525A, the memory layer 524A, the middle electrode layer 523A, the selector layer 522C and the lower electrode layer 521A by using a hard mask pattern as an etch barrier.

Referring to FIG. 5G, second conductive lines 530 may be formed over the upper electrode 525. The second conductive lines 530 may be formed by forming a conductive layer for forming the second conductive lines 530 and etching the conductive layer by using a mask pattern in a line shape extending in a second direction.

Through the above-described process, a semiconductor device including the first conductive lines 510, the memory cell 520 and the second conductive lines 530 may be formed. The memory cell 520 may include the lower electrode 521, the selector pattern 522, the middle electrode 523, the memory pattern 524 and the upper electrode 525 which are sequentially stacked.

In accordance with the implementation, the post treatment process can be performed to restore the physical damage inevitably caused by the ion implantation process during forming the selector pattern 522 so that the physical durability of the selector pattern 522 can be improved and a stress margin of layers deposited in subsequent processes can be secured. Therefore, the selector pattern 522 can operate normally. Further, since a metallic state of dopant doped in the selector pattern 522 can be preserved, it is possible to improve on/off operation characteristics of the selector pattern 522.

The substrate 500, the first conductive lines 510, the memory cell 520, the lower electrode 521, the selector pattern 522, the middle electrode 523, the memory pattern 524, the upper electrode 525 and the second conductive lines 530 shown in FIG. 5F may correspond to the substrate 400, the first conductive lines 410, the memory cell 420, the lower electrode 421, the selector pattern 422, the middle electrode 423, the memory pattern 424, the upper electrode 425 and the second conductive lines 530 shown in FIG. 4B, respectively.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A method for fabricating a selector, comprising:
forming an insulating layer;
doping the insulating layer with dopants by performing an ion implantation process; and
performing a subsequent process to the insulating layer doped with the dopants for restoring damage caused by the ion implantation process.

2. The method according to claim 1, wherein the performing of the subsequent process includes redistributing the dopants in the insulating layer such that redistributed dopants are more evenly dispersed in the insulating layer as compared to the dopants in the insulating layer before performing the subsequent process.

3. The method according to claim 1, wherein the performing of the subsequent process for restoring damage includes performing a plasma treatment process using at least one of oxygen or an inert gas as a reaction gas.

4. The method according to claim 1, wherein the performing of the subsequent process for restoring damage includes performing a plasma treatment process using a reaction gas containing no oxygen at a RF power level of 10-1000 W.

5. The method according to claim 1, wherein the performing of the subsequent process for restoring damage includes performing a plasma treatment process using a reaction gas containing oxygen at a RF power level of 100-500 W.

6. The method according to claim 1, wherein the performing of the subsequent process for restoring damage includes performing a thermal treatment process.

7. The method according to claim 6, wherein the thermal treatment process is performed at a temperature in a range of 100-400° C.

8. The method according to claim 6, wherein the thermal treatment process is performed by using at least one of oxygen or an inert gas.

9. The method according to claim 1, wherein the forming of the insulating layer forms the insulating layer to include at least one of silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride, and
wherein at least one of the dopants includes at least one of boron (B), nitrogen (N), carbon (C), phosphorous (P), arsenic (As), aluminum (Al), silicon (Si), gallium (Ga), tungsten (W), antimony (Sb), or a germanium (Ge).

10. A method for fabricating a semiconductor device, comprising:
forming an insulating layer;
doping the insulating layer with dopants by performing an ion implantation process; and
performing a subsequent process for restoring damage caused by the ion implantation process, wherein the insulating layer is formed as a selector layer after the ion implantation process and the subsequent process;
forming a memory layer over or under the selector layer; and
etching the memory layer and the selector layer by using a mask pattern to form a memory cell including a memory pattern and a selector pattern.

11. The method according to claim 10, further comprising at least one of:
forming a first electrode layer between a substrate and the selector layer, or between the substrate and a memory layer;
forming a second electrode layer between the selector layer and the memory layer; or
forming a third electrode layer over the memory layer or the selector layer.

12. The method according to claim 10, wherein the forming of the insulating layer forms the insulating layer to include at least one of silicon oxide, titanium oxide, aluminum oxide, tungsten oxide, hafnium oxide, tantalum oxide, niobium oxide, yttrium oxide, zirconium oxide, silicon nitride, titanium nitride, aluminum nitride, tungsten nitride, hafnium nitride, tantalum nitride, niobium nitride, yttrium nitride, zirconium nitride, silicon oxynitride, titanium oxynitride, aluminum oxynitride, tungsten oxynitride, hafnium oxynitride, tantalum oxynitride, niobium oxynitride, yttrium oxynitride, or zirconium oxynitride, and
wherein at least one of the dopants includes at least one of boron (B), nitrogen (N), carbon (C), phosphorous (P), arsenic (As), aluminum (Al), silicon (Si), gallium (Ga), tungsten (W), antimony (Sb), or a germanium (Ge), or a combination thereof.

13. The method according to claim 10, wherein the forming of the memory layer includes forming a material having a variable resistance characteristic that is switched between different resistance states, the material including at least one of a transition metal oxide, a phase change material, a ferroelectric material, or a ferromagnetic material.

14. The method according to claim 10, wherein the performing of the subsequent process includes redistributing the dopants in the insulating layer such that redistributed dopants are more evenly dispersed in the insulating layer as compared to the dopants in the insulating layer before performing the subsequent process.

15. The method according to claim 10, wherein the performing of the subsequent process for restoring damage includes performing a plasma treatment process using a reaction gas containing no oxygen at a RF power level of 10-1000 W.

16. The method according to claim 10, wherein the performing of the subsequent process for restoring damage includes performing a plasma treatment process using a reaction gas containing oxygen at a RF power level of 100-500 W.

17. The method according to claim 10, wherein the performing of the subsequent process for restoring damage includes performing a thermal treatment process.

18. The method according to claim 17, wherein the thermal treatment process is performed at a temperature in a range of 100-400° C.

19. The method according to claim 17, wherein the thermal treatment process is performed by using at least one of oxygen or an inert gas.
